(19) United States
(12) Patent Application Publication
(10) Pub. No.: US 2026/0081124 A1
(43) Pub. Date: Mar. 19, 2026

(54) System and Method for Optimizing Operating Parameters for E to H-Mode Transitions in a Plasma Process Chamber

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/889,427

(22) Filed: Sep. 19, 2024

(51) Int. Cl. H01J 37/32

(52) U.S. Cl. CPC H01J 37/32935; H01J 37/32174; H01J 2237/24564; H01J 2237/334

(57) ABSTRACT

A system and method for optimizing E to H-mode transitions in plasma process chambers of semiconductor manufacturing systems are disclosed. The system integrates a testing procedure, utilizing design of experiment (DOE) methodology, into a single process recipe execution, enabling real-time, data-driven adjustments of operating parameters. This approach improves the efficiency, stability, and precision of semiconductor manufacturing processes, ensuring smooth and controlled E to H-mode transitions.

### FIELD OF INVENTION

The present invention relates to semiconductor manufacturing, specifically addressing the optimization of plasma operating parameters during fabrication processes. It introduces systems and methods that employ design of experiment (DOE) techniques to gather data and optimize the operating parameters during the execution of a process recipe. The method is designed to be seamlessly integrated into the manufacturing process without causing disruptions.

### BACKGROUND

In semiconductor manufacturing, precise control of plasma processes is critical for key fabrication steps, such as etching and deposition. Traditionally, control systems like proportional-integral-derivative (PID) loops have been employed to manage plasma operating parameters. However, these approaches may not fully meet the requirements of modern semiconductor manufacturing due to their inherent latencies, particularly with the increasing complexity of plasma-based processes.

Two primary plasma modes commonly used in processing are electron (E) mode and helicon (H) mode. E-mode, or capacitive mode, typically operates at lower plasma densities and is sustained by the electric field generated by the plasma source. In contrast, H-mode, or inductive mode, operates at higher plasma densities, driven by a magnetic field produced by an RF coil, resulting in a more intense and higher-density plasma state.

A rapid and efficient E to H-mode transition is crucial, especially as advanced semiconductor processes increasingly rely on short RF pulses, often less than a few milliseconds in duration. In such processes, plasma must quickly transit to H-mode to achieve the high neutral and ion densities required. Fast and controlled transitions are vital to ensure process stability and efficiency, particularly during short RF pulses.

Achieving rapid and controlled E to H-mode transitions is essential for maintaining the integrity of advanced plasma processes and optimizing performance without introducing unintended variations or instabilities.

This invention provides an improvement over conventional practices by utilizing DOE to systematically gather data on operating parameters related to E to H-mode transitions during the execution of a single process recipe. A significant advantage of this approach is that it is implemented without interrupting the ongoing manufacturing process or affecting its outcomes.

The method allows for efficient optimization of plasma parameters while ensuring process stability. The invention focuses on selecting a portion of the RF waveform within a process step to perform the DOE analysis. This targeted approach enhances the precision of parameter optimization without causing disruptions or deviations in the semiconductor fabrication process.

### SUMMARY

The present application describes a semiconductor process system. In certain embodiments, the system includes a plasma process chamber equipped with a plasma source and a chuck configured to support a substrate during processing. The chuck is connected to a bias unit, which applies a voltage bias to accelerate ions toward the substrate. Unlike conventional process systems, this invention introduces a system controller that directly provides the operating frequency for the plasma source or the bias unit, eliminating the need for PID controls.

The process system utilizes a voltage-controlled-oscillator (VCO) to generate a pulse train with varying amplitudes. These varied amplitudes control operating frequencies for different plasma modes, such as E-mode and H-mode, facilitating smooth transitions between these modes during processing. The system controller receives a process recipe, analyzes it, and identifies process units with distinct plasma states within the process steps. The optimized operating parameters for these plasma states are determined by using a data driven approach.

In addition, the application details an inventive use of design-of-experiments (DOE) principles. The method involves selecting specific process units, representing the distinct plasma states for testing, which is seamlessly integrated into a process recipe without significantly impacting outcomes of the processing. By adjusting parameters such as frequencies and power levels, the system collects data to optimize operating parameters.

This approach reduces reliance on PID controls and mitigates the issues associated with their use. The system operates in a data-driven manner, employing statistically sound methods for parameter optimization. The invention can be applied to various plasma chamber systems used in semiconductor manufacturing, enabling real-time monitoring and optimization while maintaining process stability.

### BRIEF DESCRIPTION OF THE DRAWINGS

For enhanced clarity, the following description refers to accompanying drawings:

FIG. 1: Illustrates an exemplary process system with a conventional RF power generator.

FIG. 2A: Depicts an embodiment of a process system, equipped with a system controller to optimize operating parameters for E to H-mode transitions through the data driven approach.

FIG. 2B: Showcases an exemplary waveform design for a testing procedure.

FIG. 3: Provides an example of identifying process units and segments using an ALE process, where selected segments are utilized for designated tests conducted by the system controller.

FIG. 4: Demonstrates the allocation of selected segments within specific process units for carrying out the tests of the testing procedure.

FIG. 5: Outlines a flowchart illustrating the operation of the exemplary process system for determining the optimized operating parameters for the distinct plasma states.

### DETAILED DESCRIPTIONS

To provide a comprehensive understanding, this section elaborates on various embodiments of the present invention. Although specific details are offered for clarity, modifications and variations that fall within the scope of the claims are considered appropriate. Conventional methods and components are described to highlight the novel aspects of this invention.

### Terms Defined:

Atomic Layer Deposition (ALD): A deposition technique using plasma to enhance chemical reactions on a substrate surface. ALD typically involves dosing the substrate with precursors, followed by plasma activation to generate reactive species, such as radicals, which promote lower deposition temperatures and improved film characteristics, such as density and conformality. ALD is ideal for high-quality thin film deposition on temperature-sensitive substrates and applications requiring precise film control.

Atomic Layer Etching (ALE): A precise etching process that removes material at the atomic scale. ALE operates in cycles, including a surface modification step, followed by physical ion bombardment (sputtering) step to remove the altered layer. It offers high selectivity and control over etch depth and profile.

Bias Unit: A component that generates a controlled voltage to accelerate ions toward the substrate held by an electrostatic chuck (ESC). The bias enhances ion energy and directionality, providing precise control during etching.

Chamber: An enclosed environment used for semiconductor processes, such as etching or deposition.

Chuck: A device designed to securely hold the wafer during semiconductor manufacturing processes.

Directional Coupler: A passive device that samples a portion of an RF signal for monitoring forward and reflected power in a transmission line, ensuring efficient power management.

Electrostatic Chuck (ESC): A chuck using electrostatic forces to hold the wafer securely during processing, ensuring uniform clamping and stability.

Frequency Tuning: Adjusting the operating frequency of a system, such as an RF power generator, to optimize power transfer and minimize reflection by matching impedance.

Gas Distribution Unit: Introduces and distributes process gases across the substrate.

Implementations may include central injectors, angled injectors, or showerhead configurations, promoting even gas distribution.

Gas Source: The origin of process gases used in the vacuum chamber. A gas box may regulate flow, delivering gases under controlled conditions.

Plasma-enhanced Chemical Vapor Deposition (PECVD): a Deposition Process Where plasma energizes precursor gases, enabling film growth at lower temperatures. Commonly used for depositing dielectric layers with precise thickness and uniformity control.

Proportional-integral-derivative (PID) Control: a Control Loop Using Proportional, integral, and derivative actions to regulate variables like temperature, pressure, and gas flow. PID controls ensure stable process conditions during semiconductor fabrication.

Plasma Impedance: The opposition of plasma to alternating current (AC) or RF power, comprising resistive and reactive components. Proper impedance matching ensures efficient power transfer and stable plasma conditions.

Plasma Process Chamber: A vacuum chamber used for plasma-based processes, such as etching or deposition, where plasma activates chemical reactions or removes material.

Plasma Source: A component that generates plasma for processes like etching, deposition, or surface modification. Common types include inductively coupled plasma (ICP), transformer coupled plasma (TCP), and capacitively coupled plasma (CCP).

Plasma State: A specific condition of plasma characterized by its impedance, which includes resistive and reactive components.

Process Recipe: A detailed set of instructions and parameters for executing semiconductor processes like etching or deposition, including settings for temperature, pressure, gas flow, RF power, and timing.

Process System: Integrated equipment used to carry out various semiconductor processes, such as deposition and etching.

Process Unit: A distinct part within a process step that exhibits a distinct plasma state.

Pulsing: Modulating RF power in pulses to control the energy delivered to the plasma, enhancing etching precision and uniformity.

Reactive Ion Etching (RIE): A plasma etching technique combining ion bombardment and chemical reactions to selectively remove material with high anisotropy and precision.

Resonator: A device or component that resonates at a specific frequency, used for impedance matching in RF applications.

RF Controller: Manages RF power supplied to a plasma process chamber, ensuring precise control over RF parameters for optimized manufacturing processes.

RF Power Amplifier: Amplifies RF signals to sustain plasma for processes like etching and deposition. High-efficiency amplifiers, such as Class E amplifiers, ensure minimal power loss.

RF Power Generator: Generates RF power to energize plasma during semiconductor processes like etching or deposition.

Sheath: A boundary layer between plasma and a surface where an electric field controls ion and electron energy, influencing etching and deposition.

Substrate: The base material, usually a silicon wafer, on which semiconductor devices are fabricated.

System Controller: The central control unit managing and coordinating the process system's operations.

Transmission Line (in RF): A conductor designed to carry RF signals with minimal loss, ensuring efficient power transfer in processes like etching and deposition.

Vacuum Chamber: An enclosed space where gases are evacuated to create a low-pressure environment, essential for semiconductor processes.

Voltage-Controlled-Oscillator (VCO): An electronic oscillator that generates variable frequencies based on an input voltage, used in RF systems for precise plasma generation.

Window: A non-conductive barrier in a vacuum chamber that allows RF or microwave energy to pass through, separating the plasma generation region from external components.

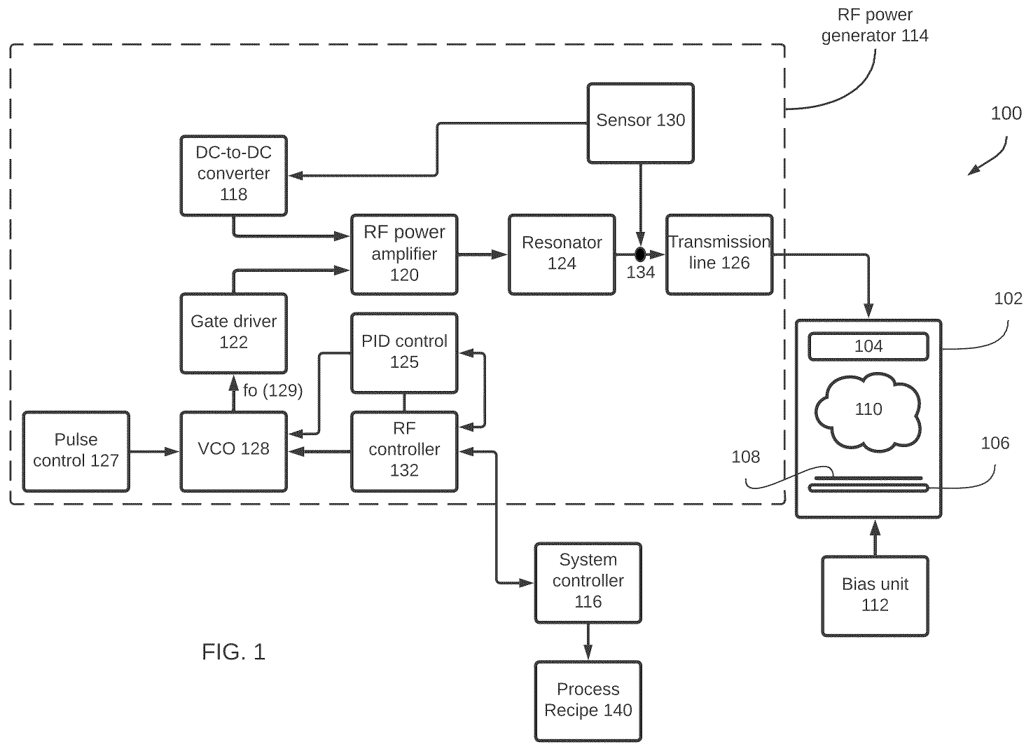

FIG. 1 illustrates a conventional process system (100) incorporating a plasma process chamber (102). The plasma source (104) is connected to an RF power generator (114), and the chamber (102) provides a vacuum environment conducive to various processing tasks. Although not shown, process gases or precursors are introduced through a gas delivery unit, and reaction byproducts are removed via a vacuum pump.

Depending on the application, the plasma source (104) can be an inductively coupled plasma (ICP) or a transformer coupled plasma (TCP), typically positioned adjacent to the vacuum chamber but isolated through a window made from dielectric materials like quartz or ceramics. RF power is supplied to a coil, generating an electromagnetic field within the chamber (102) and igniting the gases to produce plasma (110). This plasma, composed of electrons, ions, and neutrals, facilitates processes such as etching a substrate (108) supported by a chuck (106). A Process system for etching often employ a bias unit (112) to enhance ion energy through a sheath. The bias unit (112) may be an RF power generator connected to the chuck (106) or a tailored waveform generator. Both the plasma source (104) and the bias unit (112) may use pulsing technologies to refine ion energy and angular distribution, requiring synchronized operation in some implementations.

In other cases, a capacitively coupled plasma (CCP) may be used. This disclosure focuses on an ICP source paired with a bias unit (112) to explain the inventive concept across various embodiments without limiting its scope.

The RF power generator (114) includes an RF power amplifier (120), which may take various forms, such as a class E amplifier. The amplifier's output connects to the plasma source (104) through a resonator (124) and a transmission line (126). The resonator (124), typically an RF matching circuit comprising inductors, capacitors, and resistors, ensures impedance matching between the amplifier's (120) output and the load impedance presented by the chamber (102) when plasma (110) is ignited. The capacitors'capacitance may be adjustable either mechanically or electronically. Proper impedance matching is critical for efficient power transfer, particularly during plasma transitions. The transmission line (126) is vital for impedance matching, as it accounts for the impedance load created by the chamber (102).

A DC-to-DC converter (118) supplies power to the amplifier (120), modulating the DC input. A gate driver (122) interfaces with the amplifier's power MOSFETs, employing a resonant circuit to reduce power consumption at the input stage. The operating frequency fₒ (129) of the amplifier (120) is controlled by a signal generator, such as a VCO (128). RF power delivered to the plasma source (104) is often pulsed, with the pulse controller (127) connected to the VCO (128).

State-of-the-art process recipes (140) for the process system (100) often consist of multiple cyclic steps. For example, in a plasma-assisted ALE process, a cycle includes a surface modification step followed by a sputtering step, repeated multiple times. Each step may contain process units characterized by distinct plasma states with unique impedances. For instance, during surface modification, RF power may be cyclically turned on and off, with each on-phase representing a process unit. Similarly, the bias during the sputtering step may also be pulsed, with bias activation synchronized with plasma source activation in some implementations. This synchronized interval represents another distinct plasma state, referred to as another process unit. Consequently, the resonator's (124) resonating frequency may shift with each process unit due to variations in load impedance associated with the plasma state. Adjusting the operating frequency fₒ (129) is crucial when transitioning between different process units.

The frequency adjustment is managed by a PID control (125). The RF controller (132), connected to the RF power generator (114), oversees the tuning process. The controller (132) is linked to a system controller (116) that coordinates the operations of the process system (100). A sensor (130) monitors the performance of the RF power generator (114), positioned at node (134) between the resonator (124) and the transmission line (126). Using the data from this sensor (130), the RF controller (132) adjusts the VCO (128) by varying the control voltage to align the output frequency with the resonator's (124) resonating frequency.

In advanced plasma etching processes, rapid transitions between process units are essential and must occur almost instantaneously compared to the duration of the processing steps. Mechanical adjustments to the capacitor's capacitance are too slow for such transitions, making frequency tuning the preferred method for keeping the resonator (124) in resonance. However, in some implementations, variable capacitors may pre-tune the resonator (124), allowing fine frequency adjustments within a specific range determined by the resonator's bandwidth or quality factor.

Frequency adjustments can be achieved through several methods. One approach involves measuring the reflected power from the plasma process chamber (102) at node (134) using the sensor (130). A directional coupler may be used, as known in the art, to measure reflected power. If the reflected power exceeds a predetermined threshold relative to the input power from the DC-to-DC converter (118), the RF controller (132) generates a new operating frequency fₒ (129) by supplying a new control voltage to the VCO (128). To expedite the convergence of the frequency to the desired resonating frequency, a PID control (125) is typically used. This PID control (125) may be implemented digitally or in analog format.

Ordinarily, bringing the resonator (124) to its resonating state using PID control requires several milliseconds or more. In scenarios where rapid pulsing mechanisms are in operation, this latency is too prolonged. Moreover, increasing the speed of the PID control may compromise the stability of the RF power generator. While an analog PID (125) offers a shorter settling time compared to its digital counterpart, it is more susceptible to noise, such as higher-order harmonics. Any noise or fluctuations affecting phase stability make it more difficult for the system to converge to the resonating frequency. Attempts to mitigate noise, including higher-order harmonics, complicate RF circuit designs and further extend settling times. On the other hand, a digital PID (125) implementation enhances stability but may be too slow for RF power generators that require a fast response for specific applications.

In the context of plasma process chamber technology, a well-known E to H-mode transition occurs during plasma ignition. At low RF power levels, a low-density plasma with weak light emission is observed, commonly referred to as E-mode. In this mode, plasma generation primarily results from the electric field component caused by the potential difference across the individual loops of the induction coil.

As RF power is gradually increased, a significant change occurs as there is a sudden rise in electron density accompanied by increased light emission. This enhanced plasma regime, known as H-mode, is theorized to be sustained by the induced azimuthal RF electric field generated by the oscillating magnetic field.

During the E to H-mode transition, while in E-mode, both the coil current and coil voltage exhibit a gradual increase. Following the transition to H-mode, both coil current and voltage begin to decrease as RF energy is transferred from the coil to the plasma, eventually stabilizing into a steady state.

A critical point to consider is the significant variation in load impedance between the E-mode and H-mode plasma states. In H-mode, the plasma behaves like a self-induced inductor and plasma resistor, which contrasts markedly with the conditions observed during E-mode operation. This divergence in plasma characteristics complicates the task of tuning the system's operating frequency to match the resonating frequency precisely.

Since the E to H-mode transition can occur within tens of microseconds or less, the rapid shift in load impedance poses challenges to PID control stability.

It is within this specific technological context that the present invention emerges—a robust system and method designed to ensure a fast and reliable E to H-mode transition.

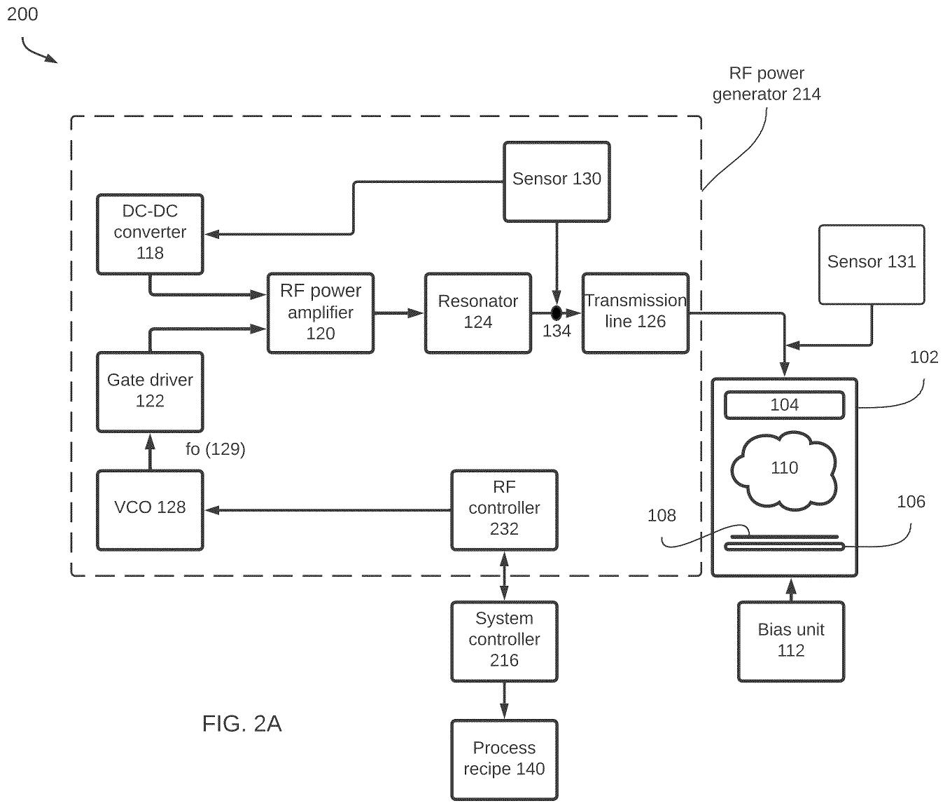

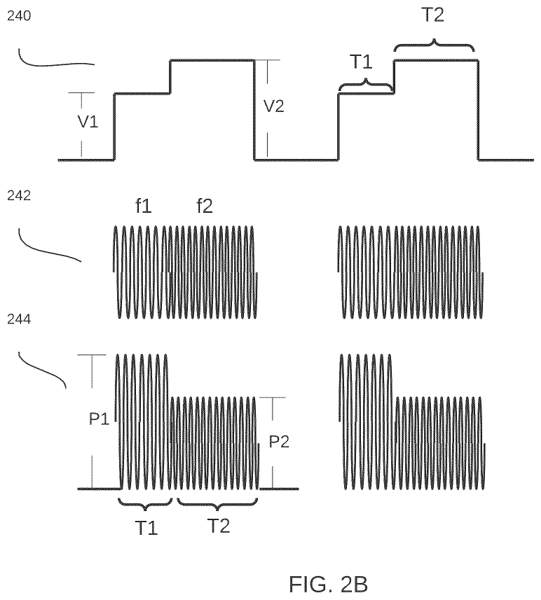

FIG. 2A illustrates a functional diagram of a representative embodiment of a process system, labeled as system (200). This system integrates a plasma process chamber (102), which includes a plasma source (104) and a chuck (106) designed to support a substrate (108) during processing. The chuck (106) is connected to a bias unit (112), which applies a voltage bias to accelerate ions toward the substrate (108). In some implementations, this voltage bias is provided by an RF generator through a blocking capacitor (not shown in the figure). The bias is frequently pulsed using a pulse generator (not shown in FIG. 2) in advanced etching processes. Alternatively, in other implementations, the voltage bias is supplied by a tailored waveform generator to achieve a tight ion energy distribution.

The RF power generator (214) is connected to the plasma source (104) of the chamber (102). The key difference between RF power generators (214) and (114) (from FIG. 1) lies in how the operating frequency fₒ (129) is generated. In the embodiment shown in FIG. 2, the system controller directly provides fₒ (129) to the RF controller (232) in RF power generator (214). The resonating frequencies for both E-mode and H-mode are established through a data-driven approach rather than using a PID control. The VCO (128) receives fₒ from the RF controller (232) by adapting to a new control voltage provided by the RF controller (232). These control voltages are delivered as a pulse train, generated by the RF controller (232), as illustrated in FIG. 2B.

The pulse train, exemplified by (240), consists of a series of sequential pulses, with each pulse corresponding to a process unit characterized by a distinct plasma state, reaching steady-state in H-mode. Each pulse is divided into two sub-pulses with different amplitudes V₁ and V₂ lasting for durations T₁ and T₂, respectively. The total pulse width is T₁+T₂ matching the duration of a process unit. V₁ and V₂ are the control voltages for the VCO (128), and these voltages generate the operating frequencies f₁ and f₂, as depicted in (242), corresponding to E-mode and H-mode operations, respectively. In one implementation, as shown in (244), a higher input power P₁ is used during E-mode than the input power P₂ in H-mode, ensuring a smooth E to H-mode transition.

The RF controller (232) determines the amplitude based on an array sent from the system controller (216), which will be described in more detail. The PID control (125) is no longer required for setting the resonator to its resonating frequency, enabling the resonator (124) to reach its resonating state within microseconds or less, a significant improvement over the previous millisecond range. Additionally, a separate pulse generator (127) is no longer necessary, as the RF controller (232) defines the duration of the process units in this embodiment.

The system controller (216) receives a process recipe (140) and analyzes it. The system controller (216) identifies steps and the corresponding process units within each step. These process units are associated with distinct plasma states, which are typically represented by individual pulses within each step. The system controller (216) may be assisted by a user in defining the process units and designing the tests.

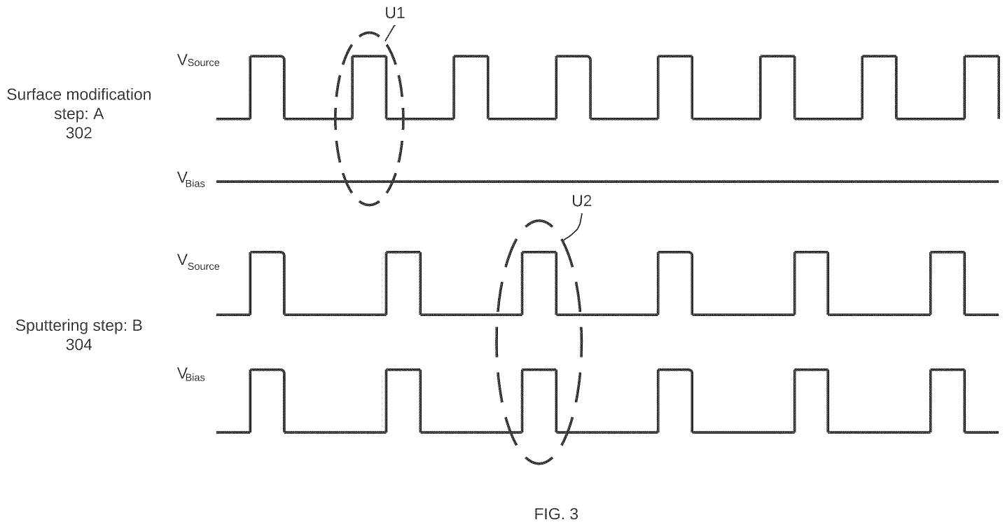

FIG. 3 illustrates a methodological approach to identifying process units with distinct plasma states, using an atomic layer etching (ALE) process as an example. The exemplary ALE process includes a surface modification step (302), labeled as “A.” During the surface modification step (302), the RF power generator (214) supplies pulsed RF power to the plasma source (104). This pulsed RF power, denoted as V_{Source}, is applied to the plasma source (104) with the goal of reducing spontaneous etching caused by ions during the surface modification step (302). It is important to note that the RF power delivered to the plasma source (104) is related not only to voltage but also to current and their phase difference, as known in the art.

Process Unit U₁ in FIG. 3 is characterized by a distinct plasma state. It can be further divided into two sub-pulses, each with different operating frequencies, f₁ and f₂, corresponding to E-mode and H-mode operations. Each sub-pulse consists of segments representing parts of the RF waveform. During the surface modification step, chemically active neutrals are generated to modify the substrate's surface (108), ensuring minimal spontaneous etching. Throughout this step, the bias unit (112), denoted as V_{Bias}, applies zero bias to the chuck (106), minimizing ion energy during the process. The surface modification step (302) weakens the bonding strength of surface atoms, setting the stage for the sputtering step (304) to remove these atoms.

Each process step, including the surface modification step and the sputtering step (304), consists of multiple process units. For example, if the surface modification step lasts one second and is pulsed at a frequency of 1.0 kHz, there would be 1,000 process units. In this embodiment, a small portion of these process units is used for a testing procedure with varied frequencies f₁ and f₂, power P₁, and time T₁ for E-mode operation. This testing can be designed using a DOE methodology, allowing for the collection of data without significantly altering the process outcome.

This core inventive concept enables the identification of optimized operating parameters for the E to H-mode transition using real-time data, rather than relying on real-time control loops. Furthermore, this method can be used as a novel approach to monitor process or equipment stability during high volume manufacturing without affecting the process outcome. The identified optimized operating parameters will ensure a smooth and reliable E to H-mode transition. Additionally, it would also identify resonating frequencies for the E-mode and H-mode for the process unit, respectively.

This methodology can be applied to any process units for any RF waveforms used in the process system (100), including those delivered to the plasma source (104) and to the chuck (106).

Notably, during the intervals between process units, no RF power is applied to either the plasma source (104) or the chuck (106), indicating that these intervals are devoid of process units.

In the sputtering step (304), labeled “B,” V_{Bias}is applied to the chuck (106) to accelerate ions, removing the modified surface layer. In some implementations, the voltage applied to the plasma source (104), V_{Source}, is pulsed in synchronization with V_{Bias} to achieve a tighter ion energy distribution. Process Unit U₂is identified as another distinct plasma state. It is important to note that the gas used during the sputtering step is often different from the gas used in the surface modification step. For example, in a silicon ALE process, chlorine may be used for surface modification, while argon is often used for sputtering. Additionally, the sputtering step is typically performed at a lower chamber pressure than the surface modification step, making U₂ a different plasma state from U₁.

In some implementations, the same method used to optimize E to H-mode transitions for U₁can be applied to U₂. However, due to the simpler nature of the E to H-mode transition in argon gas, fewer tests may be needed. In some cases, no tests are necessary, and the system controller (216) focuses solely on identifying the resonating frequency for U₂in H-mode.

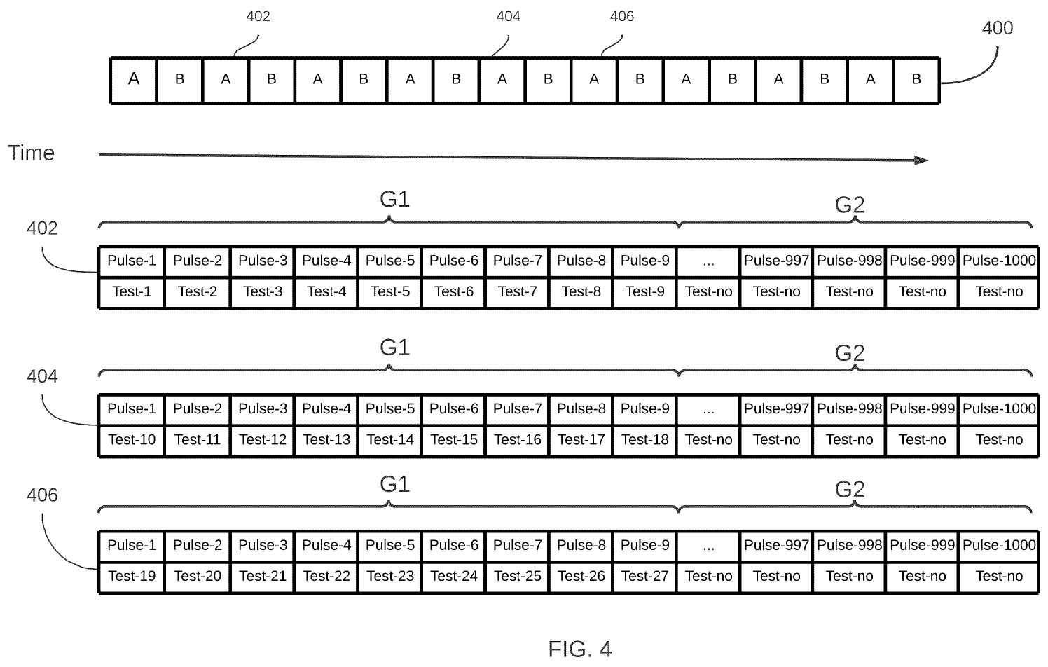

FIG. 4 shows an exemplary ALE process (400) with sequential steps A and B. Three process units (402, 404, and 406) from step A are selected for testing. For example, step A may consist of 1,000 process units or pulses. A DOE for E to H-mode transition parameters includes 27 tests, divided into three divisions with nine tests each. The system controller (216) assigns these tests across the selected process units (402, 404, and 406), dividing them into a first group G₁ and a second group G₂. The nine process units in G₁ of step (402) are assigned tests 1 through 9, while the remaining 991 units are assigned initial operating parameters for the E to H-mode transition. Similarly, the remaining 18 tests are assigned to process units in steps (404) and (406).

All unselected process steps are assigned the initial operating parameters. Once the operating parameters are assigned, the system controller (216) generates an array of process units in sequence. Each unit is associated with a specific set of operating parameters. The RF controller (232) generates a pulse train, where the pulses associated with process units in G₁ execute the varied operating parameters. The outputs are measured and collected by a first sensor (130) and a second sensor (131), as shown in FIG. 2A.

The outputs may include performance indicators for the RF power generator (214), such as reflected power from the plasma chamber (102), measured by a directional coupler as an example of the first sensor (130). The outputs can further include the current and voltage of the plasma source (104), measured by sensor (131). The ramping of voltage and current during E-mode, and the subsequent decrease after entering H-mode, provides additional insights into the E to H-mode transition.

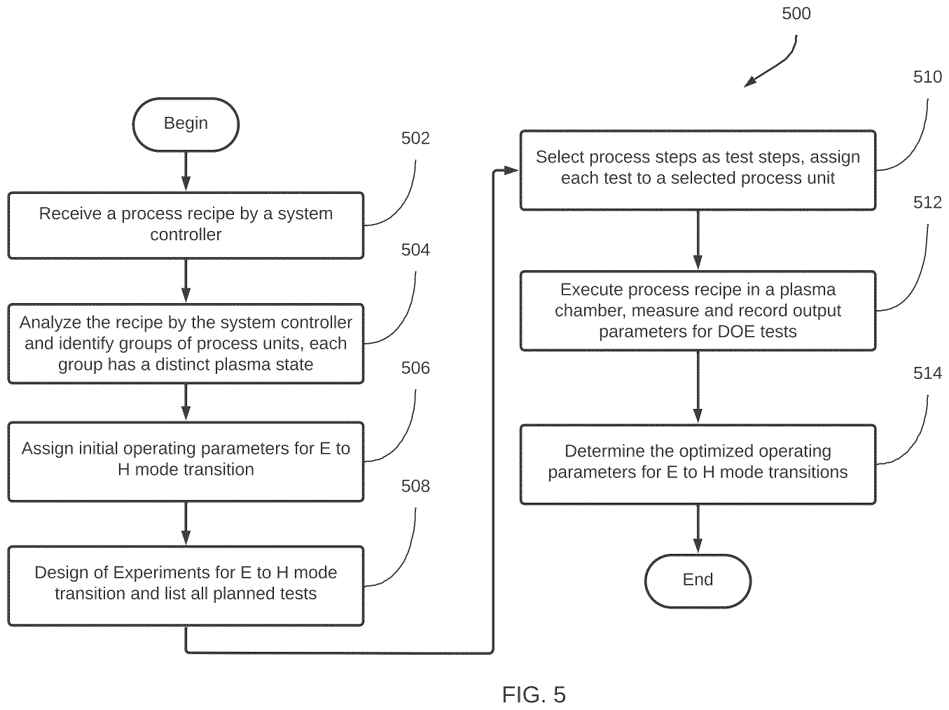

FIG. 5 outlines a flowchart of the process system in operation. The process (500) begins in step (502), where the system controller (216) receives a process recipe (140). In step (504), the system controller analyzes the recipe and identifies process units with distinct plasma states. The step (504) may be assisted by a user. In step (506), initial operating parameters for the E to H-mode transition are assigned. These parameters can be model-based or provided with the user's assistance. In step (508), a DOE with a list of tests for varied operating parameters is designed. In step (510), one or more process steps are selected for testing. The selected steps are divided into testing (G₁) and non-testing (G₂) groups, and tests are assigned to units in G₁. In step (512), the process recipe is executed, with the RF controller (232) adjusting the frequencies and time durations for E and H-mode operations, and the outputs are measured. In step (514), the best operating parameters for the E to H-mode transition are determined through analysis.

It is crucial that the operating parameters for the E to H-mode transition be established using statistically sound methods, given the complexity of the system and the random variations introduced by factors such as plasma impedance, gas flow, chamber pressure, and RF power generation. This invention's key advantage is its ability to collect a significant volume of data without impacting the process outcome.

By only testing a small fraction (0.01% to 10%) of process units, this method ensures that any variation in RF power delivery will not substantially alter the process outcome. This testing procedure can be integrated within a production recipe to monitor RF power generator performance in real-time. Additionally, the system and method are particularly suited for direct frequency generation, enabling rapid RF power generation with matched impedances without compromising process stability.

The vast amount of data collected during production allows for filtering noise in the RF system, enabling the precise determination of operating parameters for each process unit. While this example uses an ALE process, the inventive concept can be applied to other plasma chamber systems, including RIE, PECVD, ALD, and highly selective etching processes.

It should also be noted that the novel method presented herein can be executed by a machine, such as the system controller described in this disclosure. Alternatively, the method can be carried out by a user who can identify distinct plasma states, select steps and process units, form groups, design the DOE, and implement it within a process recipe. Furthermore, the method can be implemented collaboratively, where the machine and the user work together to achieve the desired outcomes. All such variations fall within the scope of the present inventive concept.

1. A process system, comprising:
a plasma process chamber configured to operate in a vacuum environment;
a radio frequency (RF) power generator coupled to a plasma source of said chamber, wherein said RF power generator further comprises an RF power amplifier, a resonator, and a voltage-controlled oscillator (VCO);
a system controller configured to regulate operations of the RF power generator through communication with an RF controller; and
a testing procedure integrated within a process recipe to determine optimized operating parameters for process units, each with a distinct plasma state, involving E to H mode transitions, wherein the testing procedure incudes selecting a portion of RF waveforms of selected process units as testing segments, each segment is assigned with one test from a list of tests designed by the system controller, wherein the optimized parameters are determined by the system controller through analyzing outputs of the tests relative to the operating parameters.

2. The system of claim 1, wherein said tests are generated by the system controller by using a design of experiments (DOE) methodology.

3. The system of claim 2, wherein the system controller can be assisted by a user in the design or selection of the tests.

4. The system of claim 1, wherein the operating parameters further include a first operating frequency for E-mode operations and a second operating frequency for the H-mode operations.

5. The system of claim 4, wherein the operating parameters further include the duration of the time allocated to E-mode operation within a total duration of the time associated with the process unit.

6. The system of claim 4, wherein the operating parameters further include a higher power level during E-mode operation compared to H-mode operation.

7. The system of claim 1, wherein the outputs of the tests include one or more performance indicators of the RF power generator, wherein the performance indicators are measured by a first sensor.

8. The system of claim 1, wherein the plasma source includes at least one coil, and wherein current and voltage measurements are recorded as outputs of the tests, captured by a second sensor.

9. The system of claim 1, wherein the testing procedure includes generating a pulse train by the RF controller, wherein a pulse train comprising a first amplitude and a second amplitude, the first amplitude serving as a first control signal directing the VCO to generate a first operating frequency for E-mode and the second amplitude serving as a second control signal directing the VCO to generate a second operating frequency for H-mode.

10. The system of claim 7, wherein the first sensor is configured to measure reflected power from said chamber.

11. A method for optimizing the transition from E to H mode in a plasma process chamber within a process system, comprising:
receiving a process recipe by a system controller;
identifying process units involving transitions from E to H mode by the system controller, wherein each process unit is associated with a distinct plasma state;
generating a testing procedure with a list of tests, by varying a set of operating parameters related to the E to H-mode transitions;
selecting a subset of RF waveforms from selected process units as testing segments;
assigning one of the tests from the list to each segment;
measuring and recording the outputs of the tests as a function of the operating parameters; and
determining optimized operating parameters for the E to H mode transitions.

12. The method of claim 11, wherein the testing procedure is designed by the system controller.

13. The method of claim 11, wherein the operating parameters include a first operating frequency for E-mode operations and a second operating frequency for H-mode operations.

14. The method of claim 13, wherein the operating parameters further include the duration of time assigned to the E-mode operation within the total duration of time associated with the process unit.

15. The method of claim 13, wherein the operating parameters further include a higher power in the E-mode compared to power consumption in the H-mode.

16. The method of claim 11, wherein the outputs of the tests include one or more performance indicators of the RF power generator, captured by a first sensor.

17. The method of claim 11, wherein the plasma source includes at least one coil, with current and voltage recorded as outputs by a second sensor.

18. The method of claim 11, further including a step in which the RF controller produces a pulse train comprising a first amplitude and a second amplitude. The first amplitude serves as a control signal directing the VCO to generate a first operating frequency for the E-mode, while the second amplitude serves as a control signal directing the VCO to generate a second operating frequency for the H-mode.

19. An ALE process system, comprising:
a plasma process chamber configured to operate in a vacuum environment;
a radio frequency (RF) power generator coupled to a plasma source of the chamber, including an RF power amplifier, a resonator, and a voltage-controlled oscillator (VCO);
a bias unit coupled to a chuck for supporting a substrate;
a system controller configured to regulate the operations of the RF power generator through communication with an RF controller; and
a testing procedure integrated within a process recipe execution to determine optimized operating parameters for E to H-mode transitions for process units associated with distinct plasma states in a surface modification and sputtering step. The testing procedure involves selecting a portion of RF waveforms as testing segments, where each segement is assigned one test from a list of tests by varying a set of operating parameters related to the E to H-mode transitions. The optimized operating parameters are determined based on measured outputs as a function of the varied operating parameters.

20. The system of claim 19, wherein the testing procedure includes a step in which the RF controller produces a pulse train comprising a first amplitude and a second amplitude. The first amplitude serves as a control signal directing the VCO to generate a first operating frequency for the E-mode, while the second amplitude serves as a control signal directing the VCO to generate a second operating frequency for the H-mode.
